(19) United States
(12) Patent Application Publication
(10) Pub. No.: US 2012/0152889 A1
(43) Pub. Date: Jun. 21, 2012

(54) METHOD FOR MANUFACTURING PIEZOELECTRIC ELEMENT

(75) Inventors: Masahisa Ueda, Susono-shi (JP); Yoshiaki Yoshida, Susono-shi (JP); Yutaka Kokaze, Susono-shi (JP)

(73) Assignee: ULVAC. INC., Chigasaki-shi (JP)

(21) Appl. No.: 13/365,652

(22) Filed: Feb. 3, 2012

Related U.S. Application Data
(63) Continuation of application No. PCT/JP10/62756, filed on Jul. 29, 2010.

(30) Foreign Application Priority Data
Aug. 6, 2009 (JP) 2009-183047

(51) Int. Cl. H01L 41/22

(52) U.S. Cl. 216/13

(57) ABSTRACT

A method for manufacturing a piezoelectric element, in which a ferroelectric film is processed in an appropriate shape by plasma etching, is provided. A metal mask made of a metal thin film which is hard to be etched by oxygen gas is placed on an object to be processed formed by laminating a lower electrode layer and a ferroelectric film on a substrate in this order. An etching gas containing a mixture gas of the oxygen gas and a reactive gas including fluorine in a chemical structure is turned into plasma and is brought into contact with the metal mask and the object to be processed. An AC voltage is applied to an electrode disposed beneath the object to be processed so that ions in the plasma are caused to enter the object to be processed to perform anisotropic etching on the ferroelectric film.

This application is a continuation of International Application No. PCT/JP2010/062756 filed on Jul. 29, 2010, which claims priority to Japanese Patent Application No. 2009-183047, filed on Aug. 6, 2009. The entire disclosures of the prior applications are herein incorporated by reference in their entireties.

### BACKGROUND OF INVENTION

The present invention generally relates to a method for manufacturing a piezoelectric element.

### BACKGROUND ART

In recent years, MEMS (Micro Electro Mechanical Systems) technology has been increasingly developing, and the application range of piezoelectric elements has expanded from industrial instruments to small electronic devices (such as, a driving source for ink discharge used in inkjet recording heads, buzzers, acceleration sensors, hand-shake correction mechanism for digital cameras and so on).

Oxide ferroelectrics, such as lead zirconate titanate (Pb (Zr, Ti) O₃, PZT), which have superior piezoelectric property, have been actively studied as materials for bridging between the mechanical stress and the change in the electric property of a piezoelectric element.

Previously, when etching a ferroelectric film by several μm in a film thickness direction, etching was performed by using a resist of an organic substance as a mask, but it was difficult to control the size, the shape and the angle of the ferroelectric film because the resist receded by etching. Also, since, resist burning (the deformation of a resist pattern) occurred if etched without cooling the substrate sufficiently even if etched by several μm, in the case of etching by several tens of μm in the film thickness direction, it was difficult to prepare the resist having film thickness which is endurable against such a prolonged etching process.

Further, ferroelectrics, such as PZT, are called hard-to-etch materials, and since the ferroelectrics have little reactivity with halogen gases and the vapor pressure of the halogenides is low, etching products easily adhere to the pattern side wall.

Reference numeral 110 in FIG. 4 denotes an object to be processed having a ferroelectric film 113 etched by a conventional technology. A lower electrode film 112 is disposed below the ferroelectric film 113; and a resist 115 is disposed on the ferroelectric film 113. A substrate 111 is disposed below the lower electrode film 112. The etching product 116 of the halogenides of the ferroelectric adheres to the side face of the resist 115 in the shape of a fence.

The etching product 116 cannot be removed in the stripping process for stripping the resist 115; and thus, it is required to newly add a removal process, and there are inconveniences, which cause wiring disconnection or insulation failure and so on in the subsequent processes for forming a wiring. See International Publication No. WO 2007/129732.

### SUMMARY OF THE INVENTION

The present invention is devised to solve the above-described inconveniences in a conventional technology;

and the object thereof is to provide a method for manufacturing a piezoelectric element in which a dielectric film is processed into a favorable shape by the use of plasma etching.

In order to solve the above described problems, the present invention is directed toward a method for manufacturing a piezoelectric element which includes a substrate, a lower electrode film of a conductive material, a ferroelectric film of an oxide ferroelectric, and an upper electrode film of a conductive material, wherein the lower electrode film, the ferroelectric film and the upper electrode film are disposed on the substrate in this order, and a shape of the ferroelectric film is deformed by applying a voltage between the upper electrode film and the lower electrode film and a deformation of the ferroelectric film returns by stopping the application of the voltage. The method for manufacturing the piezoelectric element includes a metal mask disposing step of forming a metal mask of a patterned metal thin film on the ferroelectric film of a front surface of an object to be processed having the lower electrode film and the ferroelectric film laminated on the substrate in this order and exposing a part of a surface of the ferroelectric film and covering a other part of the surface of the ferroelectric film, and an etching step of applying an AC voltage to an electrode disposed on a rear surface of the object to be processed, forming a plasma of an etching gas containing a mixture gas of an oxygen gas and a reactive gas including fluorine in its chemical structure on the front surface of the object to be processed, bringing the plasma into contact with the metal mask and the ferroelectric film and making ions in the plasma enter the metal mask and the ferroelectric film, and removing the ferroelectric film exposed at a bottom face of an opening of the metal mask to expose the lower electrode film.

The present invention is directed toward a method for manufacturing a piezoelectric element, in which the ferroelectric film contains any one of oxide ferroelectric selected from a group consisting of barium titanate (BaTiO₃), lead titanate (PbTiO₃), bismuth lanthanum titanate ((Bi,La)₄Ti₃O₁₂: BLT), lead zirconate titanate (Pb(Zr,Ti)O₃: PZT), lead lanthanum zirconate titanate ((PbLa)(ZrTi)O₃:PLZT), and strontium bismuth tantalate (SrBi₂Ta₂O₃: SBT).

The present invention is directed toward a method for manufacturing a piezoelectric element, in which the metal mask contains any one of metals selected from a group consisting of Ni, Al and Cr. The present invention is directed toward a method for manufacturing a piezoelectric element, in which the reactive gas includes any one gas or a mixture of two or more gases selected from a group consisting of CF₄, C₂F₆, C₃F₈, C₄F₈, CHF₃, SF₆, C₄F₆, and C₅F₈.

The present invention is directed toward a method for manufacturing a piezoelectric element, in which, in the etching gas, the ratio of a flow rate of the reactive gas with respect to the sum of flow rates of the oxygen gas and the reactive gas is 50% and higher.

### Effects of the Invention

Since the film thickness of a metal mask is thin and adhesion of etching products to the side wall of the metal mask is restrained, the occurrence of the wiring disconnection and so on is prevented and processing accuracy of a ferroelectric film is improved.

Also, since the metal mask has the wider range of a heatproof temperature than a conventional one, the temperature during an etching process can be controlled in a wider range than a conventional one.

Also, since it becomes possible to etch a ferroelectric film by several tens of μm in a film thickness direction, the application to MEMS becomes possible in the field in which MEMS was not able to be implemented conventionally.

Since chlorine-based gas is not used as an etching gas, a processing can be conducted even in the environment such that the usage of the chlorine-based gas is not allowed.

### BRIEF DESCRIPTION OF THE DRAWINGS

FIGS. 1 (a) to 1 (e) are figures illustrating a method for manufacturing a piezoelectric element of the present invention.

FIG. 2 is a figure illustrating a construction of an etching apparatus utilized in the present invention.

FIG. 3 is a graph showing a relationship between etching rates and etching selectivity in Ni mask and PZT film with respect to CF₄ ratio.

FIG. 4 is a figure illustrating an object to be processed after etching a ferroelectric film according to a conventional art.

### DETAILED DESCRIPTION OF THE INVENTION

### <Structure of Piezoelectric Element>

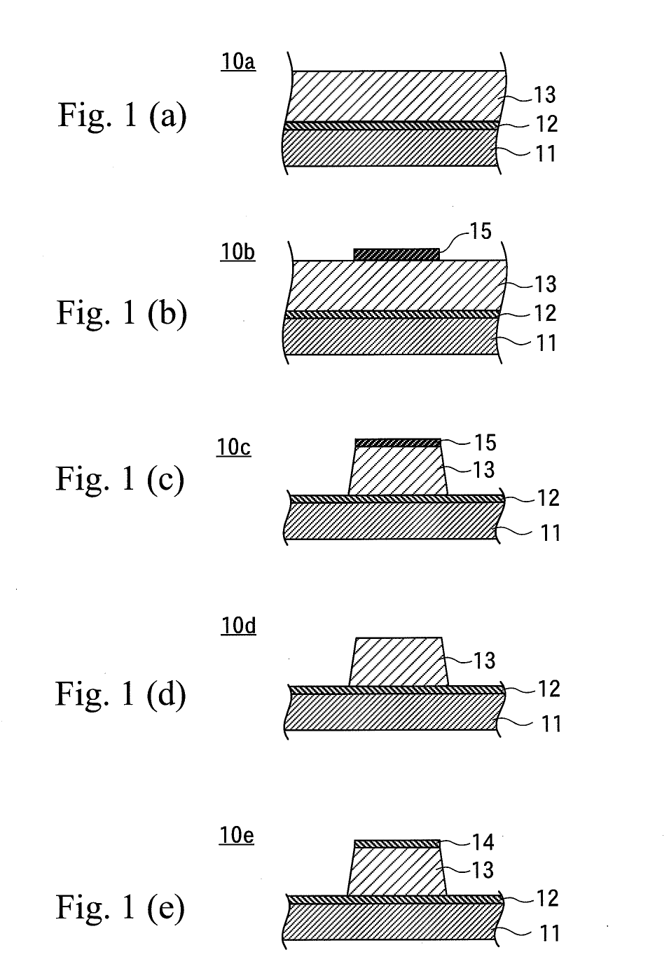

First, a structure of the piezoelectric element prepared by the manufacturing method of the present invention is explained. FIG. 1 (e) shows a cross-sectional view of a piezoelectric element 10e.

The piezoelectric element 10e has a ferroelectric film 13, an upper electrode film 14, and a lower electrode film 12.

The ferroelectric film 13 is disposed on the lower electrode film 12; and the upper electrode film 14 is disposed on the ferroelectric film 13. Beneath the lower electrode film 12, a substrate 11 is disposed.

Both the upper electrode film 14 and the lower electrode film 12 are electrically connected to a control circuit, which is not shown in the figure.

Such a piezoelectric element 10e has a piezoelectric effect; and, when the shape of the ferroelectric film 13 is deformed by applying a pressure to the ferroelectric film 13 from the outside, an electric polarization is induced in the ferroelectric film 13 and a voltage is generated between the upper electrode film 14 and the lower electrode film 12. Inversely, when a voltage is applied from the control circuit (not shown in the figure) between the upper electrode film 14 and the lower electrode film 12, the shape of the ferroelectric film 13 is deformed; and the shape thereof is restored when the application of the voltage is stopped.

The ferroelectric film 13 is formed of oxide ferroelectric; and lead zirconate titanate (Pb (Zr, Ti) O₃: PZT) is used in this embodiment.

In the present invention, the material of the ferroelectric film 13 is not limited to PZT, but the oxide ferroelectric (such as, barium titanate (BaTiO₃) , lead titanate (PbTiO₃) , bismuth lanthanum titanate ((Bi, La) ₄Ti₃O₁₂: BLT) , lead lanthanum zirconate titanate ((PbLa) (ZrTi) O₃: PLZT) , and strontium bismuth tantalate (SrBi₂Ta₂O₃: SBT)) , which can be etched by a gas containing fluorine in the chemical structure, may also be used.

The upper electrode film 14 and the lower electrode film 12 are formed of electrically-conductive materials, and a Pt film is used for both films in this embodiment. In the present invention, materials for the upper electrode film 14 and the lower electrode film 12 are not limited to Pt, but electrically-conductive materials (such as, Ir, IrO₂, SRO (Strontium Ruthenium Oxide)), which can hardly react with oxide ferroelectric, may also be used.

As for the substrate 11, a Si substrate with a thermally-oxidized film (SiO₂) is used; and the thermally-oxidized film as an insulating layer is disposed so as to contact the lower electrode film 12.

### <Manufacturing Apparatus for Piezoelectric Elements>

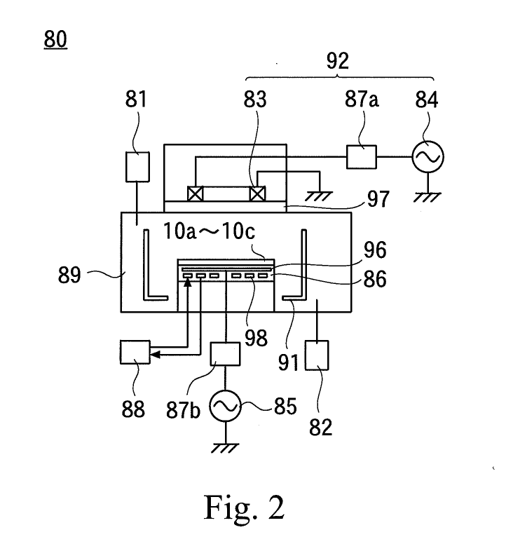

Reference numeral 80 in FIG. 2 denotes an etching apparatus in which an inductively-coupled plasma (ICP) source used in the present invention is installed.

The etching apparatus 80 has a vacuum chamber 89, a plasma generating unit 92, a gas supplying unit 81, an evacuation unit 82, and a temperature control unit 88.

Inside the vacuum chamber 89, a stage 86 to place an object to be processed thereon is provided.

The temperature control unit 88 is connected to the stage 86; and the temperature of the object to be processed placed on the stage 86 can be controlled by, for example, flowing a temperature-controlled heating medium to a cooling pipe 98 provided in the stage 86.

The plasma generating unit 92 has an RF antenna 83, a matching box 87a, and an AC source for plasma 84.

On the upper side of the vacuum chamber 89, an opening is formed; and a ceramic plate 97 (such as, a quartz plate) is provided on the opening. On the surface of the ceramic plate 97 on the outside part of the vacuum chamber 89, the RF antenna 83 is disposed. The RF antenna 83 is electrically connected to the AC source for plasma 84 via the matching box 87a; and an etching gas supplied into the vacuum chamber 89 can be turned into plasma.

Further, inside the stage 86, an electrode 96 is disposed; and when an object to be processed is placed on the stage 86, the electrode 96 is to be positioned on the back side of the object to be processed.

An AC source for sputtering 85 is electrically connected to the electrode 96 via a matching box 87b; and ions in the plasma are accelerated to collide against the object to be processed, thereby being able to etch.

Both the gas supplying unit 81 and the evacuation unit 82 are disposed outside the vacuum chamber 89. The evacuation unit 82 is connected to the inside of the vacuum chamber 89; the inside of the vacuum chamber 89 can be evacuated; the gas supplying unit 81 is connected to the inside of the vacuum chamber 89; and an etching gas can be supplied to the inside of the vacuum chamber 89.

### <A Method for Manufacturing a Piezoelectric Element>

Next, a method for manufacturing a piezoelectric element, in the present invention, is explained, with reference to FIGS. 1 (a) to (e).

Reference numeral 10a in FIG. 1 (a) denotes an object to be processed in which a lower electrode film 12 and a ferroelectric film 13 are formed on a substrate 11 in this order by the sputtering method or the like.

First, as a disposing step of a metal mask, after disposing a patterned resist film on the ferroelectric film 13, the object to be processed is dipped into an electroless nickel plating solution and nickel is deposited on the surfaces of the resist film and the ferroelectric film 13 exposed at the bottom of the opening of the resist film. After the nickel metal thin film is formed, when the resist is removed, the metal thin film on the resist is removed together with the resist, the metal thin film on the ferroelectric film 13 remains; and an object to be processed 10b in FIG. 1 (b) is obtained.

A metal mask 15 of patterned metal thin film (nickel thin film) is provided on the surface of the object to be processed 10b. The metal mask 15 is in close contact with the ferroelectric film 13; and a part of the surface of the ferroelectric film 13 is exposed and the other part thereof is covered by the metal mask 15.

Further, after dipping an object to be processed into an electroless nickel plating solution with all surfaces of the ferroelectric film 13 being exposed and forming the metal thin film of nickel on the surface of the ferroelectric film 13, a patterned resist film is formed on the surface of the formed metal thin film, and then, the metal thin film may be patterned into a predetermined shape by removing the metal thin film exposed at the bottom of the opening of the resist film by etching. Then, after removing the resist, the metal mask 15 of patterned metal thin film (nickel thin film) is obtained.

A method for disposing a metal mask in the present invention is not limited to an electroless plating method, but a metal mask may also be formed by the sputtering method or the vacuum deposition method and so on.

In short, a patterned metal thin film, which is in close contact with the ferroelectric film 13 and is thin, may be formed, and, in particular, the electroless plating method is favorable.

This is because the metal mask 15 has favorably 4 μm or more and 10 μm or less in the film thickness so that the metal mask 15 can withstand the etching in the etching process as described later, even though the metal mask 15 is thin, and the electroless plating method can achieve the above-mentioned film thickness more easily than the other method.

Material for the metal mask 15 in the present invention is not limited to Ni metal, but any material which have a slower etching rate than the etching rate for the ferroelectric film 13 with respect to the etching gas used for etching the ferroelectric film 13 and can be patterned in a predetermined shape may suffice. The metal mask 15 may be formed by metals which are hard to be etched by the oxygen gas (such as, Al, Cr, Ti, and Ta) , besides Ni, or the alloys thereof. Then, as the etching step, the inside of the vacuum chamber 89 in the etching apparatus 80 is initially evacuated by the evacuation unit 82.

The object to be processed 10b after the disposing step of disposing the metal mask is carried into the vacuum chamber 89 from a carrying-in apparatus (not shown in the figure) , while keeping a vacuum atmosphere in the vacuum chamber 89.

The object to be processed 10b is placed on the stage 86 in such a state that the opposite side of the object to be processed 10b on which the metal mask 15 is formed is faced toward the stage 86 and the side on which the metal mask 15 is formed is exposed.

While the inside of vacuum chamber 89 is evacuated, an etching gas is supplied from the gas supplying unit 81 to the inside of the vacuum chamber 89.

The etching gas contains a mixed gas of oxygen gas and a reactive gas, which includes fluorine in its chemical structure. Specifically, the reactive gas is composed of any one or a mixed gas of two or more of gases selected from a group consisting of CF₄, C₂F₆, C₃F₉, C₄F₈, CHF₃, SF₆, C₄F₆, and C₅F₈.

The etching gas may also contain an auxiliary gas composed of rare gases, such as Ar.

The gas supplying unit 81 is connected to a control apparatus (not shown in the figure), by which flow rate is controlled, and it is preferable that the ratio of the reactive gas flow rate (hereinafter called a reactive gas ratio) with respect to the sum of the flow rates of oxygen gas and the reactive gas is 50% or higher. This is because the rate of etching process is lowered as the ratio of oxygen gas becomes higher.

The side of the object to be processed on which the metal mask 15 is formed faces the RF antenna 83 via the ceramic plate 97. When the AC source for plasma 84 is activated and AC current is applied to the RF antenna 83 to cause the RF antenna 83 to radiate an electric wave while putting the vacuum chamber 89 to ground potential, the electric wave enters the inside of the vacuum chamber 89 through the ceramic plate 97.

The space between the ceramic plate 97 and the side of the object to be processed on which the metal mask 15 is formed is in an etching gas atmosphere; and the electric wave is irradiated with the etching gas, whereby plasma of the etching gas is formed on the metal mask 15 of the object to be processed. Plasma may be formed by other methods.

In the plasma, active species (such as, ions of the etching gas or radicals) are contained.

In addition, when generating the plasma and performing the etching, the AC source for sputtering 85 is activated to apply an AC voltage to the electrode 96, so that ions of the etching gas in the plasma and the auxiliary gas can be drawn to the side of the object to be processed 10b without charging the object to be processed. When the portion of the ferroelectric film 13 exposed out of the metal mask 15 contacts the plasma, the portion reacts with the plasma and etching products of the ferroelectric film 13 are produced.

Among the etching products, gaseous products are removed by vacuum evacuation; and those products adhering to the object to be processed are sputtered by ions drawn by the electrode 96 and are removed out of the surface of the object to be processed.

Since the film thickness of the metal mask 15 is equal to or smaller than 10 μm, adhesion of the etching products to the side face of the metal mask 15 is restrained.

Since the metal mask 15 formed of a metal thin film has heat resistance, gasification of the etching products may be accelerated by controlling the temperature of the object to be processed 10b on the stage 86 at a temperature higher than a room temperature when cooling the object to be processed by the temperature control unit 88.

As shown in the object to be processed 10c in FIG. 1(c), when the lower electrode film 12 is exposed, the AC source for plasma 84 and the AC source for sputtering 85 are deactivated, respectively, and supply of the etching gas from the gas supplying unit 81 is stopped.

Here, a shield 91 is provided so as to surround the stage 86 and prevents adhesion of attached materials produced by etching to the inner wall of the vacuum chamber 89. Then, the object to be processed 10c, after the etching step, is taken out of the etching apparatus 80; and a remover solution, which can selectively remove the metal mask 15, is brought into contact with the surface of the object to be processed 10c. The metal mask 15 is dissolved by the remover solution and is removed, whereby the object to be processed 10d after removal of the metal mask as shown in FIG. 1(d) can be obtained.

Next, the upper electrode film 14 is disposed on the upward looking face of the ferroelectric film 13 of the object to be processed 10d, whereby the piezoelectric element 10e as shown in FIG. 1(e) is produced.

The upper electrode film 14 can be also disposed after forming the ferroelectric film 13.

### EMBODIMENTS

### Embodiment 1

A PZT film made of PZT was formed on a substrate by the sputtering method and so forth, and then, an object to be processed, in which a Ni mask made of Ni was disposed on the PZT film with the PZT film partly exposed, was carried into the vacuum chamber of the etching apparatus. A temperature control unit is activated, so that the temperature of the object to be processed was controlled so as to be kept at 20° C.

While evacuating the inside of the vacuum chamber, O₂ gas, at a flow rate of 8.4×10⁻³Pa·m³/sec(5 sccm), and CF₄ gas, at a flow rate of 7.6×10⁻²Pa·m³/sec (45 sccm), were supplied into the inside of the vacuum chamber, as an etching gas, and then the pressure inside the vacuum chamber was set at 0.5 Pa. Here, the flow rate ratio of CF₄ gas with respect to the sum of the flow rates of O₂ gas and CF₄ gas (hereinafter, called CF₄ ratio) is 0.9.

The etching gas was turned into plasma by applying AC power of 600 W to the RF antenna 83 from an AC source for plasma, and was brought into contact with the object to be processed. Also, by applying AC power of 400 W to an electrode beneath the object to be processed from an AC source for sputtering, ions in the plasma were caused to enter the object to be processed, and the PZT film was partly subjected to anisotropic etching. Here, etching rates for each of the PZT film and the Ni mask were measured.

Then, the CF₄ ratio of the etching gas supplied into the vacuum chamber was varied to 0.8 by controlling the gas supplying unit; and etching rates for each of the PZT film and the Ni mask were measured.

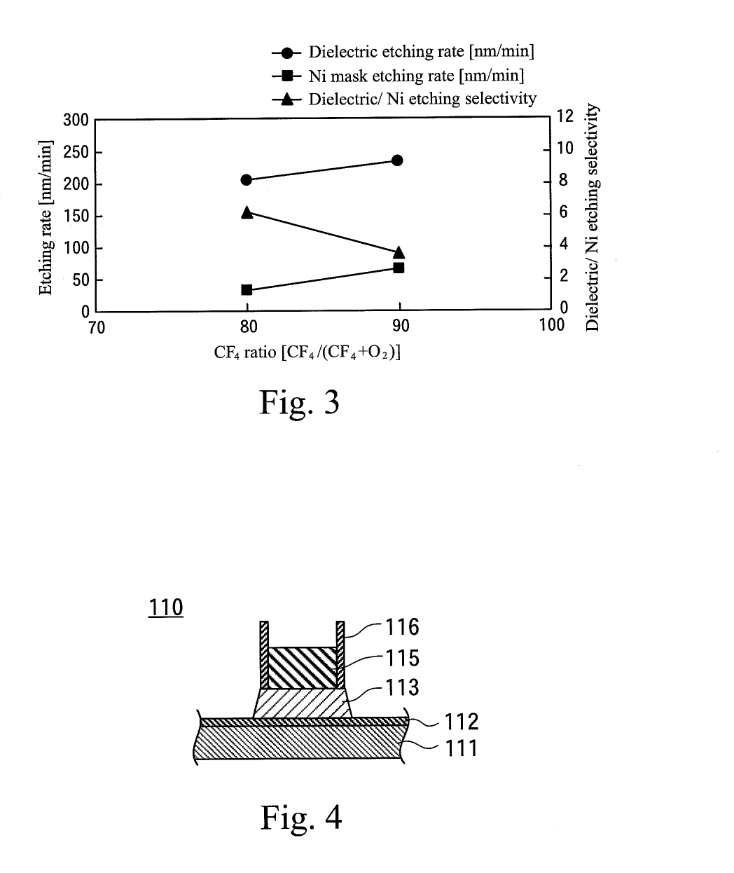

FIG. 3 shows a relation between CF₄ ratio and measured results of each etching rate . Also, a relation between CF₄ ratio and the etching selectivity of the PZT film with respect to the Ni mask is also shown in this figure.

It is found that, as the CF₄ ratio decreased, each etching rate decreased, respectively, but the etching selectivity of the PZT film with respect to the Ni mask increased.

### Embodiment 2

A PZT film made of PZT was formed on a substrate by the sputtering method and so forth; and an object to be processed, in which a Ni mask made of Ni was disposed on the PZT film with the PZT film partly exposed, was photographed by a scanning electron microscope (SEM).

This object to be processed was carried into the vacuum chamber of the etching apparatus; a mixture gas of O₂ gas and CF₄ gas, as an etching gas, was supplied into the vacuum chamber; and then, the etching gas was turned into plasma to perform etching.

Then, after completion of the etching, the object to be processed was taken out of the vacuum chamber and was photographed by the SEM.

The etched side face was formed with a taper angle of 70°, and no etching products adhered to the side wall.

### Comparative Example 1

In the same way as the Embodiment 2, an object to be processed, in which a resist made of organic material was disposed on a PZT film with the PZT film partly exposed, was photographed by a SEM.

This object to be processed was carried into the vacuum chamber of the etching apparatus as described in the Embodiment 2, a mixture gas of O₂ gas and CF₄ gas, as an etching gas, was supplied into the vacuum chamber; and then, the etching gas was turned into plasma to perform etching.

Then, after completion of etching, the object to be processed was taken out of the vacuum chamber and was photographed by the SEM.

Etching products adhered to the side face of the resist.

What is claimed is:

1. A method for manufacturing a piezoelectric element which includes a substrate, a lower electrode film of a conductive material, a ferroelectric film of an oxide ferroelectric, and an upper electrode film of a conductive material,
wherein the lower electrode film, the ferroelectric film and the upper electrode film are disposed on the substrate in this order, and a shape of the ferroelectric film is deformed by applying a voltage between the upper electrode film and the lower electrode film and a deformation of the ferroelectric film returns by stopping the application of the voltage,
the method for manufacturing the piezoelectric element, comprising:
a metal mask disposing step of forming a metal mask of a patterned metal thin film on the ferroelectric film of a front surface of an object to be processed having the lower electrode film and the ferroelectric film laminated on the substrate in this order and exposing a part of a surface of the ferroelectric film and covering another part of the surface of the ferroelectric film; and
an etching step of applying an AC voltage to an electrode disposed on a rear surface of the object to be processed, forming a plasma of an etching gas containing a mixture gas of an oxygen gas and a reactive gas including fluorine in its chemical structure on the front surface of the object to be processed, bringing the plasma into contact with the metal mask and the ferroelectric film and making ions in the plasma enter the metal mask and the ferroelectric film, and removing the ferroelectric film exposed at a bottom face of an opening of the metal mask to expose the lower electrode film.

2. The method for manufacturing the piezoelectric element according to claim 1, wherein the ferroelectric film contains anyone of oxide ferroelectric selected from a group consisting of barium titanate (BaTiO₃), lead titanate (PbTiO₃), bismuth lanthanum titanate ((Bi,La)₄Ti₃O₁₂: BLT), lead zirconate titanate (Pb(Zr,Ti)O₃: PZT), lead lanthanum zirconate titanate ((PbLa) (ZrTi)O₃: PLZT), and strontium bismuth tantalate (SrBi₂Ta₂O₃: SBT).

3. The method for manufacturing the piezoelectric element according to claim 1, wherein the metal mask contains any one of metals selected from a group consisting of Ni, Al and Cr.

4. The method for manufacturing the piezoelectric element according to claim 1, wherein the reactive gas includes any one gas or a mixture gas of at least two gases selected from a group consisting of CF₄, C₂F₆, C₃F₈, C₄F₈, CHF₃, SF₆, C₄F₆, and C₅F₈.

5. The method for manufacturing the piezoelectric element according to claim 1, wherein, in the etching gas, the ratio of a flow rate of the reactive gas with respect to the sum of flow rates of the oxygen gas and the reactive gas is at least 50%.
